(19) United States
(12) Patent Application Publication
(10) Pub. No.: US 2014/0122004 A1
(43) Pub. Date: May 1, 2014

(54) CALCULATING APPARATUS, MAGNETIC RESONANCE SYSTEM, POWER CONSUMPTION CALCULATING METHOD AND PROGRAM

(71) Applicant: GE Medical Systems Global Technology Company, LLC, Waukesha, WI (US)

(72) Inventor: Yusuke Asaba, Toyko (JP)

(73) Assignee: GE MEDICAL SYSTEMS GLOBAL TECHNOLOGY COMPANY, LLC, Waukesha, WI (US)

(21) Appl. No.: 14/068,505

(22) Filed: Oct. 31, 2013

(30) Foreign Application Priority Data
Oct. 31, 2012 (JP) 2012-240291

(51) Int. Cl. G01R 27/02

(52) U.S. Cl. CPC G01R 27/02
USPC 702/65

(57) ABSTRACT

A calculating apparatus is provided. The calculating apparatus includes a resistance calculating unit configured to calculate, based on a pulse width of a gradient pulse generated by a gradient coil, a resistance of the gradient coil at the time that the gradient coil generates the gradient pulse, and a power consumption calculating unit configured to calculate power consumption of the gradient coil, based on the resistance of the gradient coil.

### CROSS REFERENCE TO RELATED APPLICATIONS

This application claims the benefit of Japanese Patent Application No. 2012-240291 filed Oct. 31, 2012, which is hereby incorporated by reference in its entirety.

### BACKGROUND OF THE INVENTION

The present invention relates to a calculating apparatus which calculates power consumption of each of gradient coils, a magnetic resonance system to which the calculating apparatus is applied, a power consumption calculating method for calculating the power consumption of the gradient coil, and a program for calculating the power consumption of the gradient coil.

A high-speed imaging method like an echo planar imaging (EPI) method has recently been adopted. With its adoption, a problem has arisen in that power applied to each of gradient coils increases dramatically and the gradient coil generates heat. There has therefore been disclosed an MRI system that allows gradient coils to be operated consecutively in a range in which the temperature of each gradient coil does not reach an upper limit temperature (see, e.g., Japanese Unexamined Patent Publication No. 2000-023939).

There is however a limit to power outputable by a gradient magnetic field power supply. Thus, a magnetic resonance system needs to generate a gradient magnetic field within a range of power outputable by the gradient magnetic field power supply. Therefore, a calculation model is needed which can predict whether the output power of the gradient magnetic field power supply falls within an allowable range before the generation of the gradient magnetic field.

As such a calculation model, there has been known a DC model. In the DC model, however, the value of a resistance used in the calculation of a loss of each gradient coil is constant regardless of the value of a frequency. Thus, the DC model has a problem in that the higher the frequency, the larger the error in the calculated value of power.

On the other hand, there has been known an AC model in which the difference between frequency components has been taken into consideration. As compared with the DC model, the AC model is capable of reducing the error in the calculated value of power. The AC model is however accompanied by a problem that Fourier transform is needed to calculate power and there is a need to resample the waveform of a gradient magnetic field at fine intervals, thus resulting in time being taken to calculate the power.

It is thus desired that the power consumption of each gradient coil is calculated in a short period of time.

### BRIEF DESCRIPTION OF THE INVENTION

In a first aspect, a calculating apparatus is provided. The calculating apparatus includes a resistance calculating unit which calculates, based on a pulse width of each of gradient pulses generated by gradient coils, a resistance of the gradient coil at the time that the gradient coil generates the gradient pulse, and a power consumption calculating unit which calculates power consumption of the gradient coil, based on the resistance of the gradient coil.

In a second aspect, the calculating apparatus described in the first aspect is provided, in which the resistance calculating unit calculates the resistance of the gradient coil, based on parameters determined according to the gradient coil and the pulse width.

In a third aspect, the calculating apparatus described in the first or second aspect is provided, including a pulse width calculating unit which calculates the pulse width, based on point data indicative of characteristic points of a waveform of the gradient pulse.

In a fourth aspect, the calculating apparatus described in the third aspect is provided, including a coil current calculating unit which calculates a coil current of the gradient coil, based on the point data.

In a fifth aspect, the calculating apparatus described in the fourth aspect is provided, in which the coil current calculating unit calculates a gradient magnetic field intensity of the gradient coil, based on the point data and calculates the coil current, based on the gradient magnetic field intensity.

In a sixth aspect, the calculating apparatus described in any one of the first through third aspects is provided, in which the characteristic points of the waveform of the gradient pulse are a point at which the gradient of the gradient pulse changes, and a point at which the gradient magnetic field intensity of the gradient pulse is zero.

In a seventh aspect, a magnetic resonance system having gradient coils is provided. The magnetic resonance system includes a resistance calculating unit which calculates, based on a pulse width of each of gradient pulses generated by the gradient coils, a resistance of the gradient coil at the time that the gradient coil generates the gradient pulse, and a power consumption calculating unit which calculates power consumption of the gradient coil, based on the resistance of the gradient coil.

In an eighth aspect, a power consumption calculating method is provided. The method includes calculating, based on a pulse width of each of gradient pulses generated by gradient coils, a resistance of the gradient coil at the time that the gradient coil generates the gradient pulse, and calculating power consumption of the gradient coil, based on the resistance of the gradient coil.

In a ninth aspect, a program is provided. The program is configured to cause a computer to execute a resistance calculating process for calculating, based on a pulse width of each of gradient pulses generated by gradient coils, a resistance of the gradient coil at the time that the gradient coil generates the gradient pulse, and a power consumption calculating process for calculating power consumption of the gradient coil, based on the resistance of the gradient coil.

Since the resistance of each gradient coil can be calculated based on a pulse width, the power consumption of the gradient coil can be calculated in a short time.

Further advantages will be apparent from the following description of exemplary embodiments as illustrated in the accompanying drawings.

### BRIEF DESCRIPTION OF THE DRAWINGS

FIG. 1 is a schematic diagram of an exemplary magnetic resonance system.

FIG. 2 is a pulse sequence used to describe a method of estimating power consumption.

FIG. 3 is a graph schematically showing the relationship between a pulse width W and a resistance Rdc.

FIG. 4 is a diagram illustrating one example of a flow used upon calculating power consumption of gradient coils 23x, 23y and 23z.

FIGS. 5A-5C are diagrams showing one example of gradient pulses generated by the gradient coils 23x, 23y and 23z, respectively.

FIGS. 6A-6C are explanatory diagrams of point data.

FIG. 7 is an explanatory diagram of one example of a method of calculating a pulse width W of a gradient pulse x1.

FIG. 8 is a diagram showing a resistance Rdc_x of the gradient coil 23x, which is calculated for every x1, . . . , x4 of gradient pulses.

FIG. 9 is a diagram showing a resistance Rdc_y of the gradient coil 23y, which is calculated for each of gradient pulses y1 and y2.

FIG. 10 is a diagram showing a resistance Rdc_z of the gradient coil 23z, which is calculated for every z1, . . . , z3 of gradient pulses.

FIG. 11 is a diagram showing a coil current Ix of the gradient coil 23x, which is calculated for every x1, . . . , x4 of the gradient pulses.

FIG. 12 is a diagram showing a coil current Iy of the gradient coil 23y, which is calculated for each of the gradient pulses y1 and y2.

FIG. 13 is a diagram showing a coil current Iz of the gradient coil 23y, which is calculated for every z1, . . . , z3 of the gradient pulses.

FIG. 14 is a graph illustrating the difference between power consumption calculated by an AC model and power consumption calculated by a DC model.

FIG. 15 is a graph illustrating the difference between power consumption calculated by an AC model and power consumption calculated by an exemplary method.

### DETAILED DESCRIPTION OF THE INVENTION

Exemplary embodiments will hereinafter be described. The disclosure is however not limited to the following exemplary embodiments.

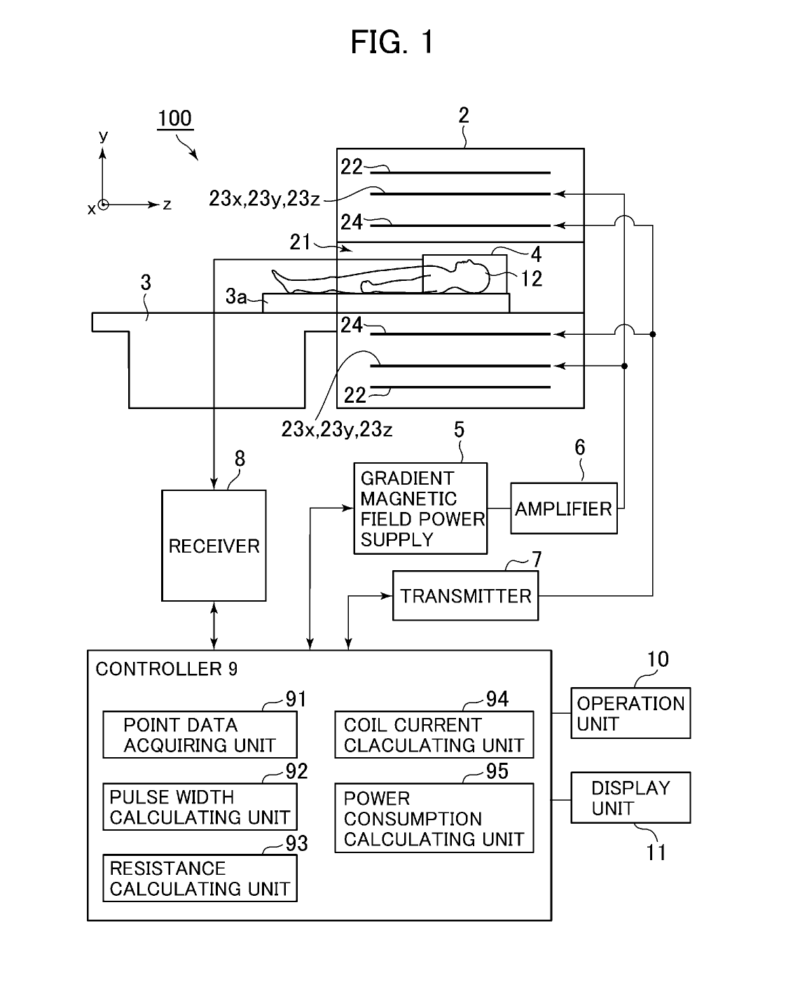

FIG. 1 is a schematic diagram of an exemplary magnetic resonance system.

The magnetic resonance system (hereinafter called “MR system”, where MR is Magnetic Resonance) 100 has a magnet 2, a table 3, a receiving coil 4, etc.

The magnet 2 has a bore 21 in which a subject 12 is accommodated. Also, the magnet 2 has a superconductive coil 22, gradient coils 23x, 23y and 23z, and an RF coil 24. The superconductive coil 22 forms a static magnetic field. The gradient coil 23x forms a gradient magnetic field in an x-axis direction, the gradient coil 23y forms a gradient magnetic field in a y-axis direction, and the gradient coil 23z forms a gradient magnetic field in a z-axis direction. The RF coil 24 transmits an RF pulse. Incidentally, a permanent magnet may be used instead of the superconductive coil 22.

The table 3 has a cradle 3a that supports the subject 12. The cradle 3a is configured so as to be movable into the bore 21. The subject 12 is carried in the bore 21 by the cradle 3a.

The receiving coil 4 is attached to the head of the subject 12. The receiving coil 4 receives magnetic resonance signals from the subject 12.

The MR system 100 further includes a gradient magnetic field power supply 5, an amplifier 6, a transmitter 7, a receiver 8, a controller 9, an operation unit 10 and a display unit 11, etc.

The gradient magnetic field power supply 5 outputs a gradient magnetic field signal. The gradient magnetic field signal is amplified by the amplifier 6, followed by being supplied to the gradient coils 23x, 23y and 23z.

The transmitter 7 supplies current to the RF coil 24. The receiver 8 performs signal processing such as detection on the signals received from the receiving coil 4.

The controller 9 controls the operations of respective parts of the MR system 100 so as to realize various operations of the MR system 100 such as transmission of information necessary for the display unit 11, reconstruction of an image based on data received from the receiver 8, etc. The controller 9 has a point data acquiring unit 91 through a power consumption calculating unit 95, etc.

The point data acquiring unit 91 acquires point data of gradient pulses generated by the gradient coils 23x, 23y and 23z from data of pulse sequences. The point data will be described later.

The pulse width calculating unit 92 calculates the pulse width of each gradient pulse, based on the point data.

The resistance calculating unit 93 calculates the resistance of each gradient coil, based on the pulse width.

The coil current calculating unit 94 calculates a coil current that flows through each gradient coil.

The power consumption calculating unit 95 calculates power consumption of each gradient coil.

The controller 9 is one example that configures the point data acquiring unit 91 through the power consumption calculating unit 95 and functions as these units by executing a predetermined program. The controller 9 corresponds to a calculating apparatus.

The operation unit 10 is operated by an operator and inputs various information to the controller 9. The display unit 11 displays various information thereon.

The MR system 100 is configured in the above-described manner.

In the exemplary embodiment, the power consumption used up by each of the gradient coils 23x, 23y and 23z is estimated before each of the gradient coils 23x, 23y and 23z generates the gradient pulse. The gradient magnetic field power supply 5 outputs a gradient magnetic field signal to the amplifier 6, based on the estimated power consumption. A description will hereinafter be made of how to estimate the power consumption of the gradient coils 23x, 23y and 23z in the exemplary embodiment.

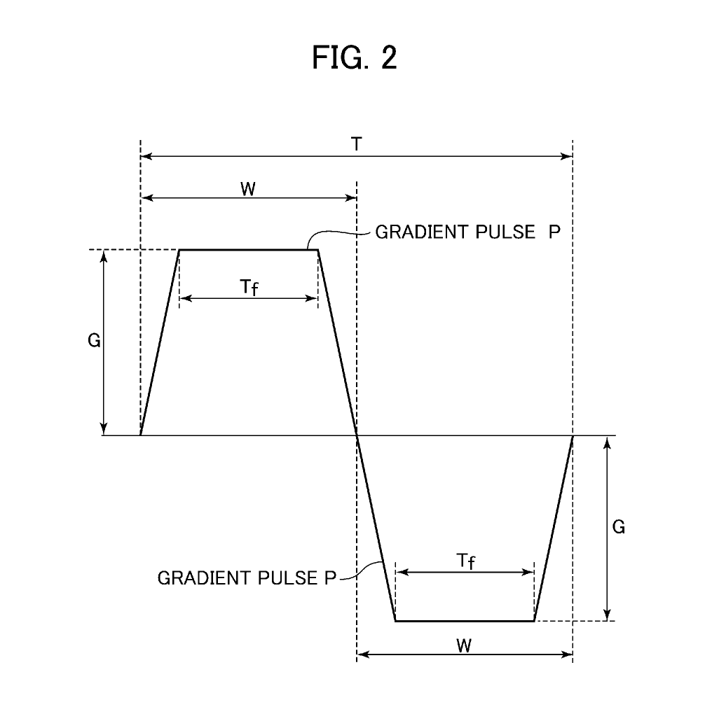

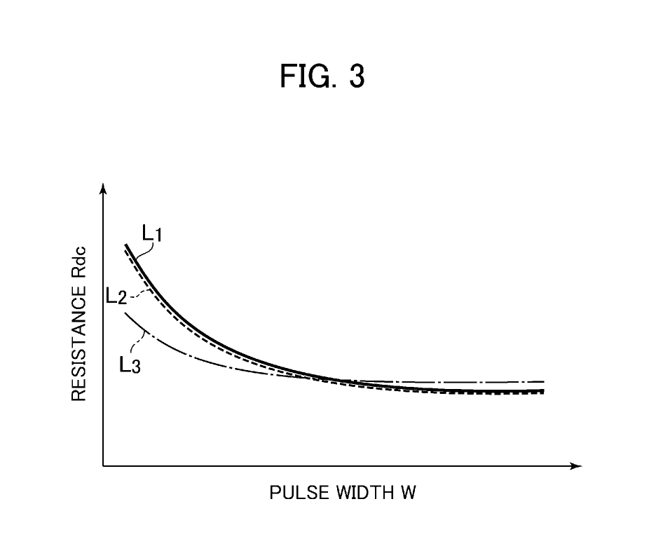

FIGS. 2 and 3 are diagrams for describing a method of estimating the power consumption of the gradient coils 23x, 23y and 23z in the exemplary embodiment.

First consider where each of the gradient coils 23x, 23y and 23z generates a pulse sequence shown in FIG. 2. In this case, the resistance Rdc of each of the gradient coils 23x, 23y and 23z can be expressed in the following Equation 1:

$$Rdc = \frac{P a c}{\int {i ( t )}^{2} d t} T \qquad Equation 1$$

where Pac is power consumption calculated by AC model,

i(t) is coil current flowing through each of gradient coils 23x, 23y and 23z, and

T is period of pulse sequence.

Now consider a resistance Rdc obtained when a pulse width W of a gradient pulse P is changed while a slew rate SR of the gradient pulse P remains at a fixed value. When the pulse width W of the gradient pulse P is changed, the relationship between the pulse width W of the gradient pulse P and the resistance Rdc can be represented by the following graph (refer to FIG. 3).

FIG. 3 is a graph schematically showing the relationship between the pulse width W and the resistance Rdc.

A curve L1 (solid line), a curve L2 (broken line) and a curve L3 (one-dot chain line) are shown in the graph. The curves L1, L2 and L3 represent the following relationships:

Curve L1: relationship between pulse width W and resistance Rdc of gradient coil 23x,

Curve L2: relationship between pulse width W and resistance Rdc of gradient coil 23y, and

Curve L3: relationship between pulse width W and resistance Rdc of gradient coil 23z.

The relationship between the pulse width W and the resistance Rdc can be expressed by the following Equation 2 from these curves L1, L2 and L3:

$$Rdc = A + B \times {\{ \frac{1}{{log}_{10} ( \frac{W}{D} )} \}}^{C} \qquad Equation 2$$

where parameters A, B, C and D are values determined by each gradient coil. Thus, when the parameters A, B, C and D of the gradient coil 23x are assumed to be expressed in A=Ax, B=Bx, C=Cx and D=Dx respectively, the resistance Rdc_x of the gradient coil 23x can be expressed in the following Equation 3x:

$$Rdc\_x = Ax + Bx \times {\{ \frac{1}{{log}_{10} ( \frac{W}{Dx} )} \}}^{Cx} \qquad Equation 3 x$$

When the parameters of the gradient coil 23y are assumed to be expressed in A=Ay, B=By, C=Cy and D=Dy respectively, the resistance Rdc_y of the gradient coil 23y can be expressed in the following equation:

$$Rdc\_y = Ay + By \times {\{ \frac{1}{{log}_{10} ( \frac{W}{Dy} )} \}}^{Cy} \qquad Equation 3 y$$

Likewise, when the parameters of the gradient coil 23z are assumed to be expressed in A=Az, B=Bz, C=Cz and D=Dz, the resistance Rdc_z of the gradient coil 23z can be expressed in the following equation:

$$Rdc\_z = Az + Bz \times {\{ \frac{1}{{log}_{10} ( \frac{W}{Dz} )} \}}^{Cz} \qquad Equation 3 z$$

Thus, if the pulse widths W are determined from the Equation 3x through Equation 3z, then the resistances of the gradient coils 23x, 23y and 23z at the time that they generate the gradient pulses can be determined.

Here, the power consumption of the gradient coils 23x, 23y and 23z are respectively assumed to be expressed in Pac_x, Pac_y and Pac_z. The power consumption Pac_x, Pac_y and Pac_z are represented by the following Equations 4x-4z using the resistances Rdc_x, Rdc_y and Rdc_z respectively:

Pac_{—}x=Ix²×Rdc_{—}x Equation 4x

Pac_{—}y=Iy²×Rdc_{—}y Equation 4y

Pac_{—}z=Iz2×Rdc_{—}z Equation 4z

where Ix is coil current flowing through gradient coil 23x,

Iy is coil current flowing through gradient coil 23y, and

Iz is coil current flowing through gradient coil 23z.

The resistances Rdc_x, Rdc_y and Rdc_z can be calculated from the pulse widths W. The coil currents Ix, Iy and Iz can be calculated from the gradient magnetic field intensities G of the gradient pulses. Accordingly, the power consumption Pac_x, Pac_y and Pac_z of the gradient coils 23x, 23y and 23z can be estimated from Equation 4x through Equation 4z.

One example of a flow for estimating power consumption of each gradient coil in the exemplary embodiment will next be described.

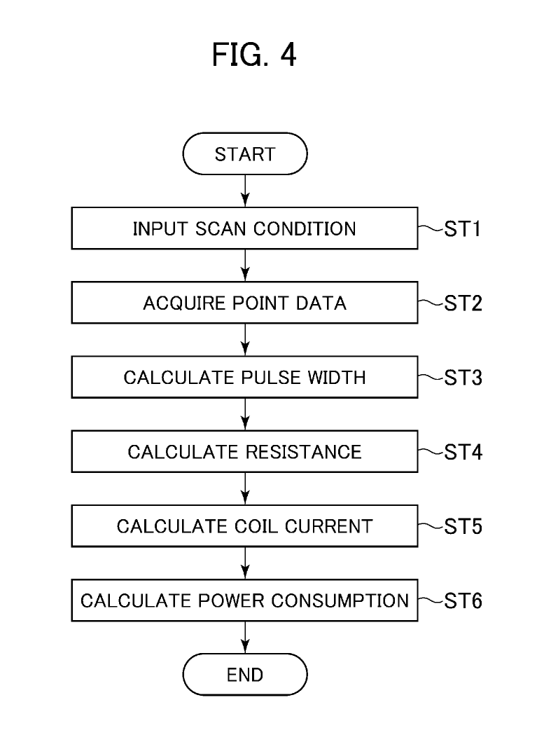

FIG. 4 is a diagram showing one example of a flow described when the power consumption of the gradient coils 23x, 23y and 23z are calculated.

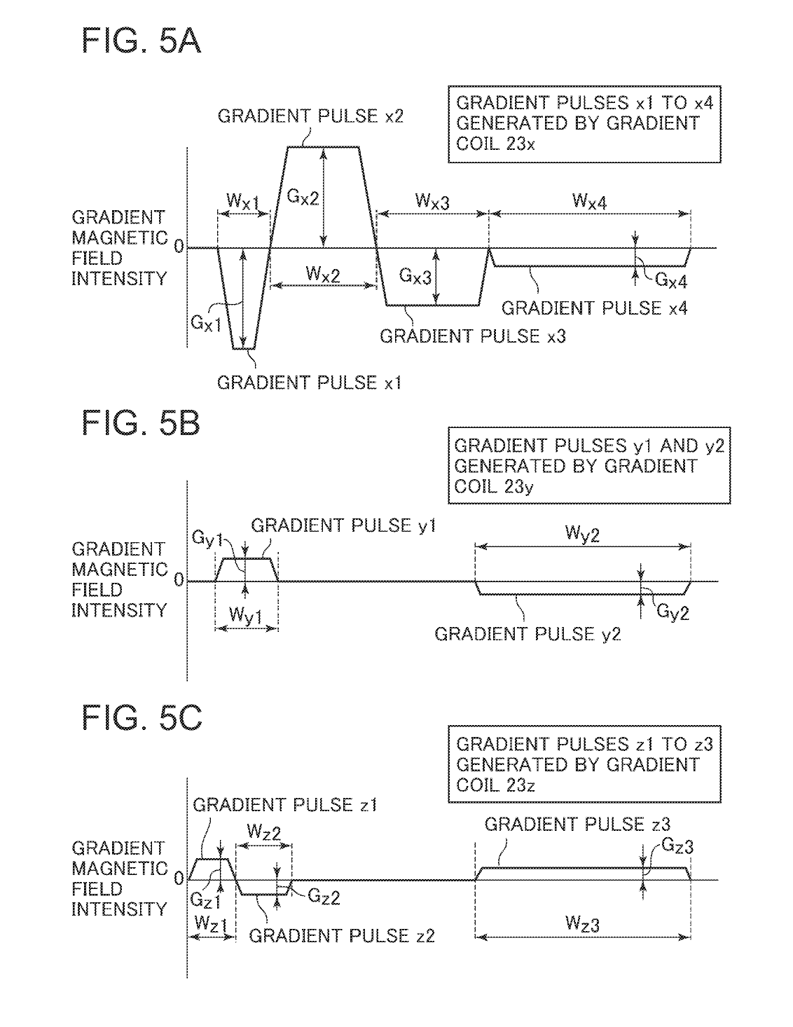

At Step ST1, an operator inputs a scan condition. Thus, a pulse sequence used when a subject is imaged is determined. Accordingly, an RF pulse that the RF coil 24 transmits, gradient pulses generated by the gradient coils 23x, 23y and 23z are determined. FIGS. 5A-5C show one example illustrative of the gradient pulses generated by the gradient coils 23x, 23y and 23z, respectively. After the scan condition has been inputted, the flow proceeds to Step ST2.

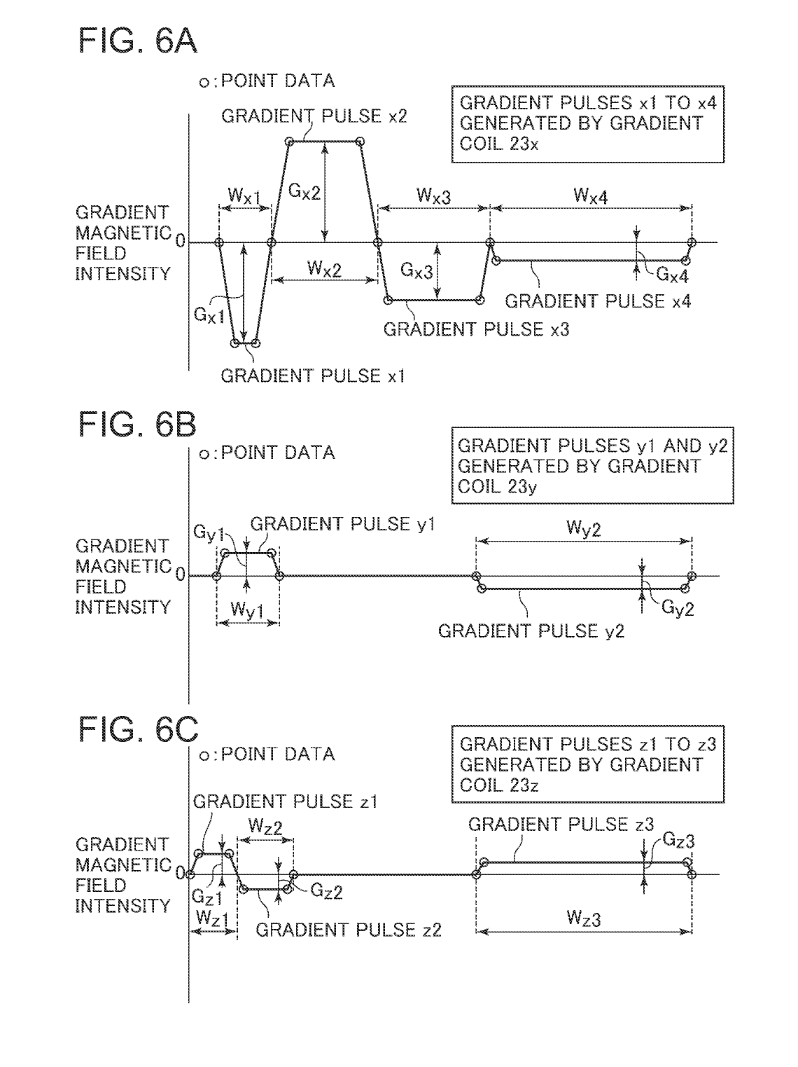

At Step ST2, the point data acquiring unit 91 (refer to FIG. 1) acquires point data of the gradient pulses generated by the gradient coils 23x, 23y and 23z from data of pulse sequences (refer to FIGS. 6A-6C).

FIGS. 6A-6C are diagrams for describing the point data.

The point data represent characteristic points of the waveforms of the gradient pulses. In the exemplary embodiment, the following points are defined as the characteristic points of the waveforms of the gradient pulses:

(1) point at which the gradient of each gradient pulse changes, and

(2) point at which the gradient magnetic field intensity of each gradient pulse is zero.

After the acquisition of the point data of the gradient pulses generated by the gradient coils 23x, 23y and 23z, the flow proceeds to Step ST3.

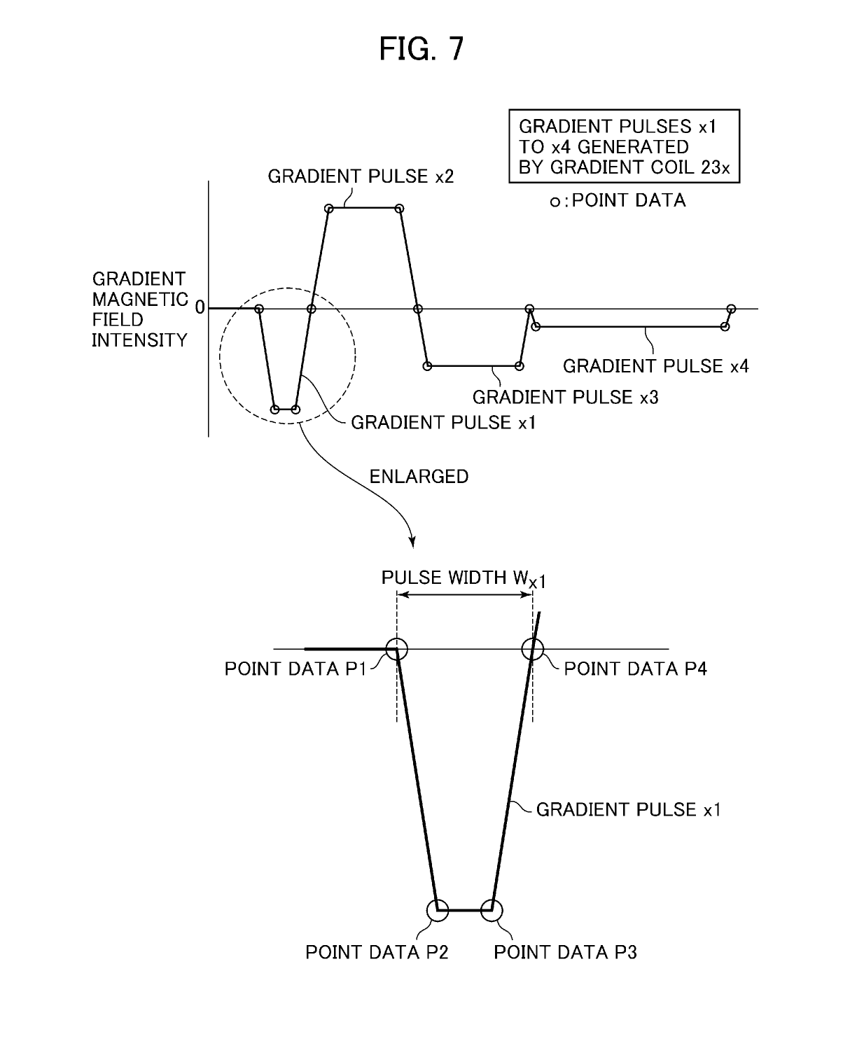

At Step ST3, the pulse width calculating unit 92 (refer to FIG. 1) calculates the pulse width of each gradient pulse, based on the point data. A method of calculating the pulse width of each gradient pulse will be explained below referring to FIG. 7. Incidentally, a method of calculating the pulse width of the gradient pulse x1 will be explained in FIG. 7 for convenience of explanation, but the pulse widths of other gradient pulses can also be calculated by the same calculation method as the method of calculating the pulse width of the gradient pulse x1.

FIG. 7 is an explanatory diagram of one example of the method of calculating the pulse width W of the gradient pulse x1.

First, the pulse width calculating unit 92 detect from point data P1 through P4 for specifying the waveform of the gradient pulse x1, the point data P1 and P4 zero in gradient magnetic field intensity. Next, the pulse width calculating unit 92 calculates a time interval between the point data P1 and P4. Since the pulse width Wx1 of the gradient pulse x1 is a time taken until the gradient magnetic field intensity of the gradient pulse x1 reaches from zero to zero again, the pulse width Wx1 of the gradient pulse x1 can be calculated by calculating the time interval between the point data P1 and P4.

While the method of calculating the pulse width Wx1 of the gradient pulse x1 has been described in FIG. 7, the pulse widths Wx2 through Wx4 of other gradient pulses x2 through x4 can also be calculated by similar methods. Further, the pulse widths Wy1 and Wy2 of gradient pulses y1 and y2 generated by the gradient coil 23y, and the pulse widths Wz1 through Wz3 of gradient pulses z1 through z3 generated by the gradient coil 23z can also be calculated by similar methods. After the pulse widths of the respective gradient pulses have been calculated, the flow proceeds to Step ST4.

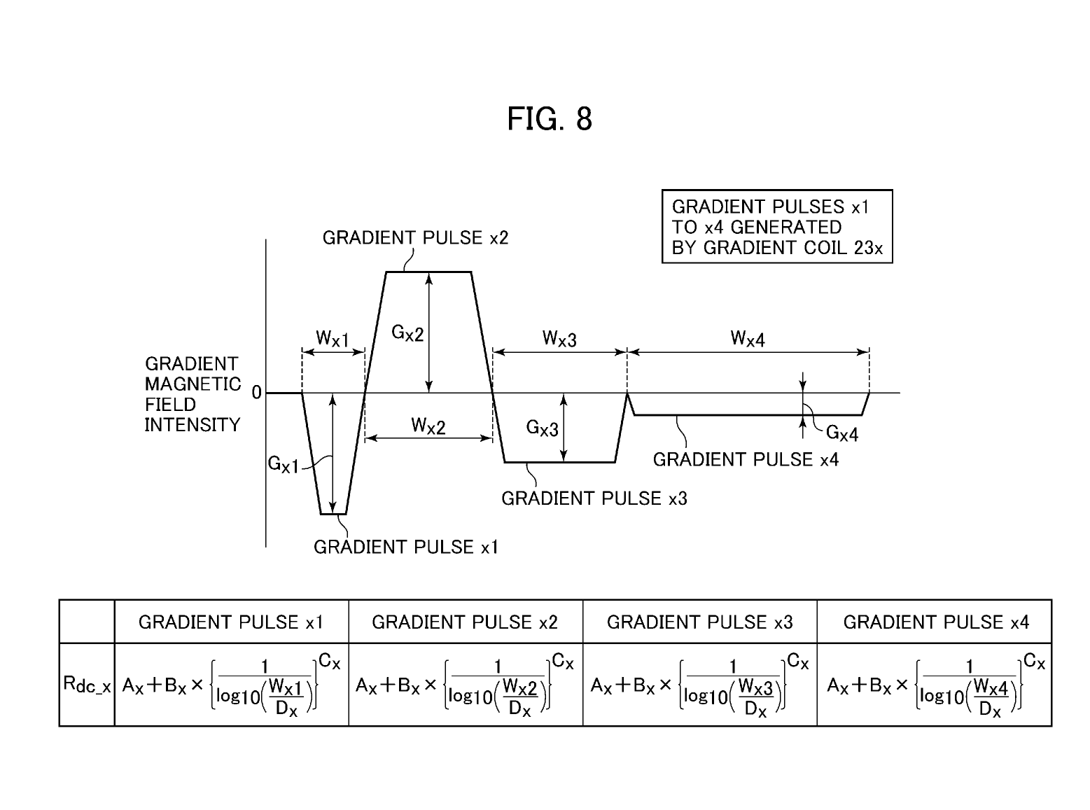

At Step ST4, the resistance calculating unit 93 (refer to FIG. 1) substitutes the pulse widths calculated at Step ST3 into Equation 3x through Equation 3z to calculate the resistances of the gradient coils. For example, when the resistance Rdc_x of the gradient coil 23x is determined, the pulse width of each of the gradient pulses x1 through x4 may be substituted into the Equation 3x. Substituting the value of the pulse width of each of the gradient pulses x1 through x4 enables determination of the resistance Rdc_x of the gradient coil 23x at the time that it generates each of the gradient pulses x1 through x4. FIG. 8 shows the resistance Rdc_x of the gradient coil 23x calculated for every x1, . . . , x4 of the gradient pulses.

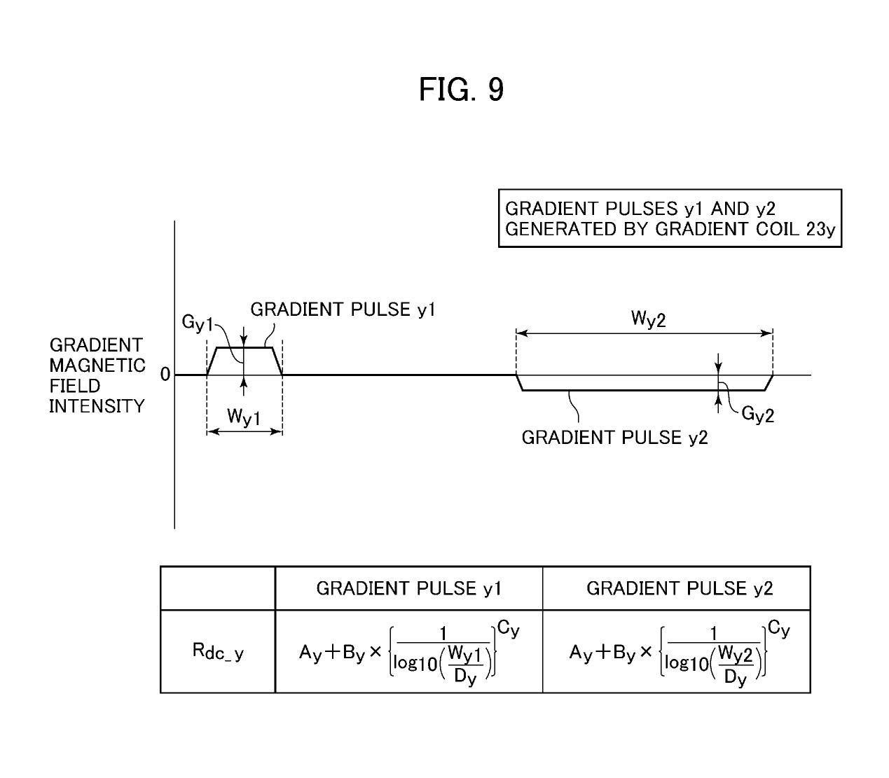

When the resistance Rdc_y of the gradient coil 23y is determined, the pulse width of each of the gradient pulses y1 and y2 may be substituted into the Equation 3y. It is thus possible to determine the resistance Rdc_y of the gradient coil 23y for each of the gradient pulses y1 and y2. FIG. 9 shows the resistance Rdc_y of the gradient coil 23y calculated for each of the gradient pulse y1 and y2.

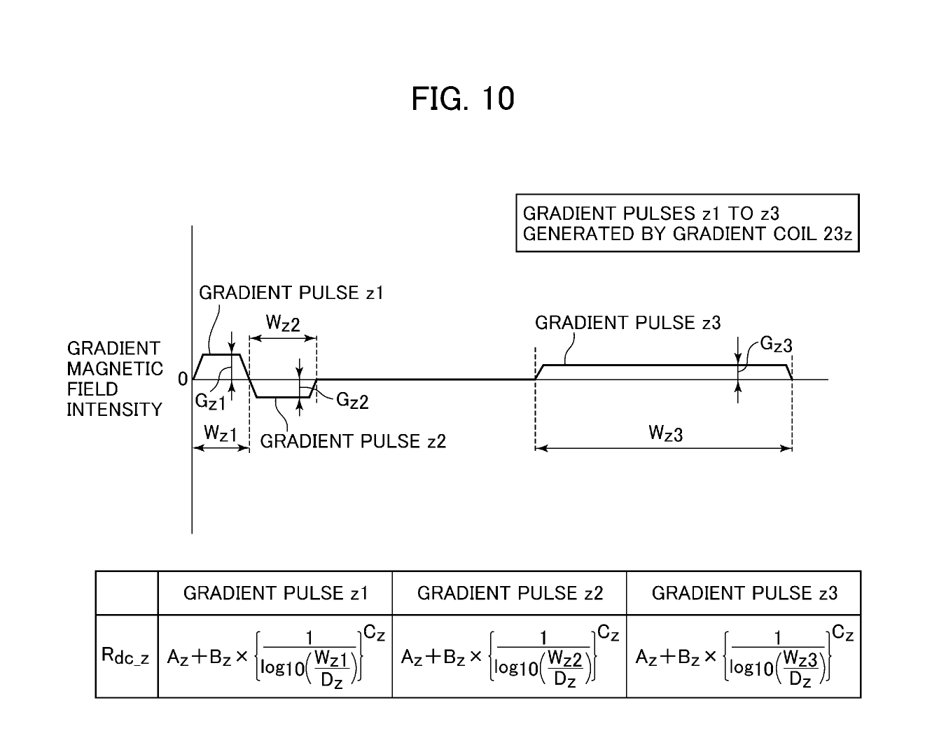

Further, when the resistance Rdc_z of the gradient coil 23z is determined, the pulse width of each of the gradient pulses z1 through z3 may be substituted into the Equation 3z. It is thus possible to determine the resistance Rdc_z of the gradient coil 23z for every z1, . . . , z3 of the gradient pulses. FIG. 10 shows the resistance Rdc_z of the gradient coil 23z calculated for every z1, . . . , z3 of the gradient pulses.

After the resistances of the gradient coils 23x, 23y and 23z have been calculated for every gradient pulse, the flow proceeds to Step ST5.

At Step ST5, the coil current calculating unit 94 (refer to FIG. 1) calculates the coil current Ix flowing through the gradient coil 23x, the coil current Iy flowing through the gradient coil 23y and the coil current Iz flowing through the gradient coil 23z.

The coil current Ix flowing through the gradient coil 23x can be calculated by the following Equation 5x, for example:

Ix=(Gx/Gmax_{—}x)×Imax_{—}x Equation 5x

where Gmax_x is a maximum value of gradient magnetic field intensity capable of being generated by gradient coil 23x,

Imax_x is coil current necessary to generate gradient magnetic field intensity Gmax_x, and

Gx is a gradient magnetic field intensity of each of gradient pulses x1 through x4.

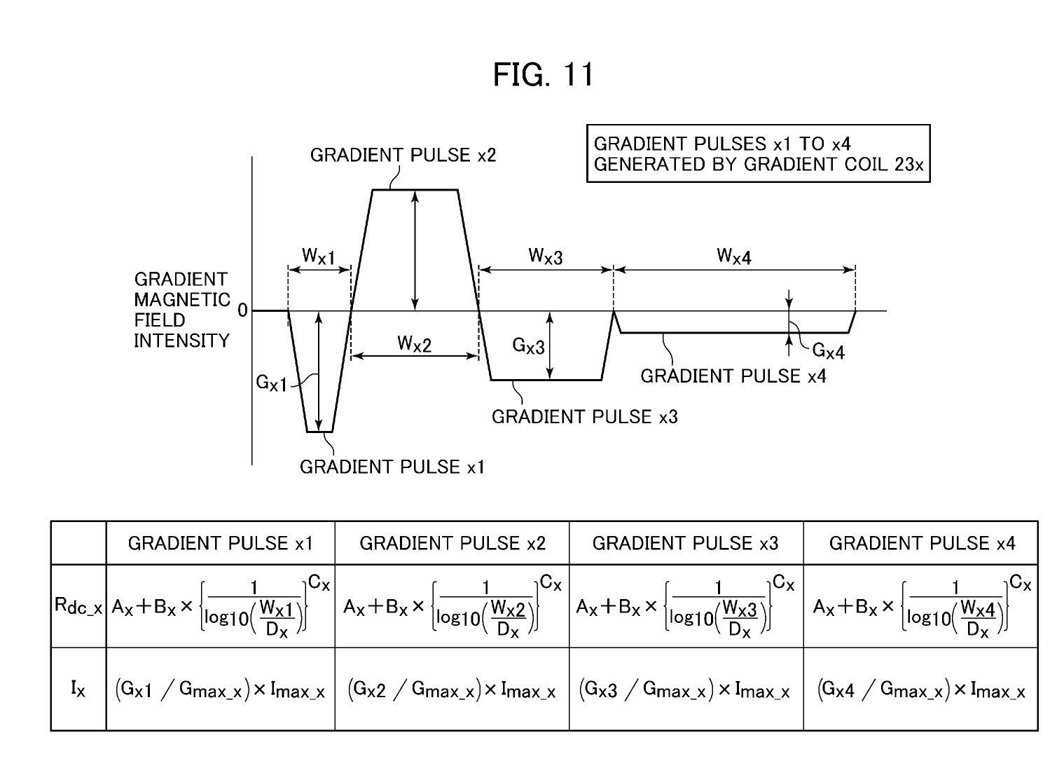

Gmax_x and Imax_x are respectively values determined in advance before the subject is scanned. Thus, substituting the value of the gradient magnetic field intensity G of each of the gradient pulses x1 through x4 into the Equation 5x enables the calculation of the coil current Ix flowing through the gradient coil 23x when each of the gradient pulses x1 through x4 is generated. FIG. 11 shows the coil current Ix of the gradient coil 23x calculated for every x1, . . . , x4 of the gradient pulses.

The coil current Iy flowing through the gradient coil 23y can be calculated by the following Equation 5y:

Iy=(Gy/Gmax_{—}y)×Imax_{—}y Equation 5y

where Gmax_y is a maximum value of gradient magnetic field intensity capable of being generated by gradient coil 23y,

Imax_y is a coil current necessary to generate gradient magnetic field intensity Gmax_y, and

Gy is a gradient magnetic field intensity of each of gradient pulses y1 and y2.

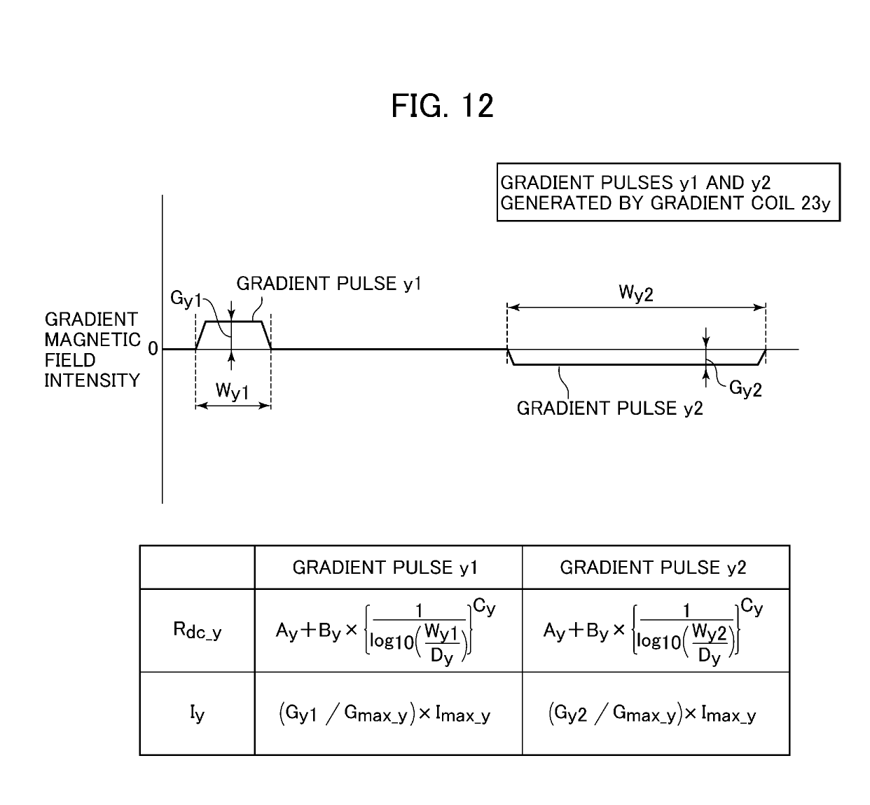

FIG. 12 shows the coil current Iy of the gradient coil 23y calculated for each of the gradient pulses y1 and y2.

Likewise, the coil current Iz flowing through the gradient coil 23z can be calculated by the following Equation 5z:

Iz=(Gz/Gmax_{—}z)×Imax_{—}z Equation 5z

where Gmax_z is a maximum value of gradient magnetic field intensity capable of being generated by gradient coil 23z,

Imax_z is a coil current necessary to generate gradient magnetic field intensity Gmax_z, and

Gz is a gradient magnetic field intensity of_each of gradient pulses z1 through z3.

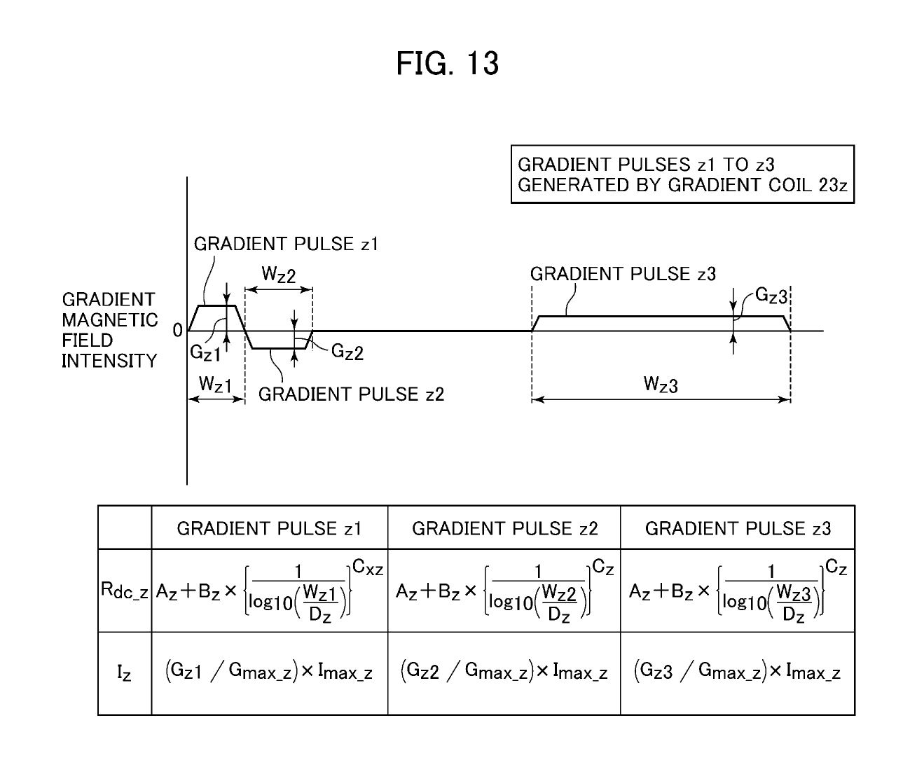

FIG. 13 shows the coil current Iz of the gradient coil 23z calculated for every z1, . . . , z3 of the gradient pulses.

After the coil currents Ix, Iy and Iz have been calculated, the flow proceeds to Step ST6.

At Step ST6, the power consumption calculating unit 95 (refer to FIG. 1) calculates the power consumption Pac_x of the gradient coil 23x, the power consumption Pac_y of the gradient coil 23y and the power consumption Pac_z of the gradient coil 23z. These power consumption Pac_x, Pac_y and Pac_z can be calculated by the above Equations 4x through 4z.

The resistances Rdc_x, Rdc_y and Rdc_z in the Equations 4x through 4z have been calculated at Step ST4 (refer to FIGS. 8 through 10). The coil currents Ix, Iy and Iz in the Equations 4x through 4z have been calculated at Step ST5 (refer to FIGS. 11 through 13). Thus, the power consumption of the gradient coils 23x, 23y and 23z can be calculated for every gradient pulse by substituting the resistances Rdc_x, Rdc_y and Rdc_z calculated at Step ST4 and the coil current Ix, Iy and Iz calculated at Step ST5 into the Equations 4x through 4z. Referring to FIG. 11, for example, the resistance Rdc_x and the coil current Ix are represented by the following Equations 6 and 7 in regard to the gradient pulse xl generated by the gradient coil 23x.

$$\begin{matrix}Rdc\_x = Ax + Bx {\{ \frac{1}{{log}_{10} ( \frac{Wx 1}{Dx} )} \}}^{Cx} & Equation 6 \\ Ix = ( Gx 1 / Gmax\_x ) Imax\_x & Equation 7\end{matrix}$$

Thus, the power consumption Pac_x at the time that the gradient coil 23x generates the gradient pulse x1 can be calculated by substituting Equations 6 and 7 into Equation 4x. Subsequently, in the same manner as above, the power consumption Pac_x at the time that the gradient coil 23x generates each of the gradient pulses x2, x3 and x4 can also be calculated by substituting the resistance Rdc_x and coil current Ix determined for every x2, . . . , x4 of the gradient pulses into Equation 4x. It is thus possible to calculate the power consumption of the gradient coil 23x for every x1, . . . , x4 of the gradient pulses.

The power consumption Pac_y of the gradient coil 23y can be calculated by substituting the resistance Rdc_y and coil current Iy determined for each of the gradient pulses y1 and y2 into the Equation 4y. Likewise, the power consumption Pac_z of the gradient coil 23z can be calculated by substituting the resistance Rdc_y and coil current Iy determined for every z1, . . . , z3 of the gradient pulses into the Equation 4z.

All the power consumption are calculated in this manner and the flow is completed.

In the exemplary embodiment, the point data indicative of the point at which the gradient of each gradient pulse changes, and the point data indicative of the point at which the gradient magnetic field intensity of each gradient pulse is zero, are acquired at Step ST2. The pulse width and gradient magnetic field intensity of each gradient pulse are calculated by these point data. Substituting the pulse width of each gradient pulse into each of Equations 3x through 3z makes it possible to calculate the resistance of each gradient coil. Substituting the gradient magnetic field intensity of each gradient pulse into each of Equations 5x through 5z enables the coil current of each gradient coil to be calculated. Then, the power consumption of each gradient coil can be calculated by substituting the resistance and coil current of the gradient coil into each of Equations 4x through 4z. Thus, in the exemplary embodiment, the power consumption of each gradient coil can be calculated even without performing Fourier transform or resampling the gradient pulses at fine intervals, thus making it possible to shorten the time required to calculate the power consumption as compared with the AC model.

Also in the embodiment, the resistances of the gradient coils and the power consumption thereof are calculated based on Equations 1 through 5z. The resistances of the gradient coils and the power consumption thereof may however be calculated using equations different from the above equations.

Incidentally, in order to verify how much errors in power consumption calculated by the method of the exemplary embodiment exist, the power consumption of the gradient coils were calculated using three methods described below with respect to thirty pulse sequences.

(1) DC model,

(2) AC model, and

(3) Method of the exemplary embodiment.

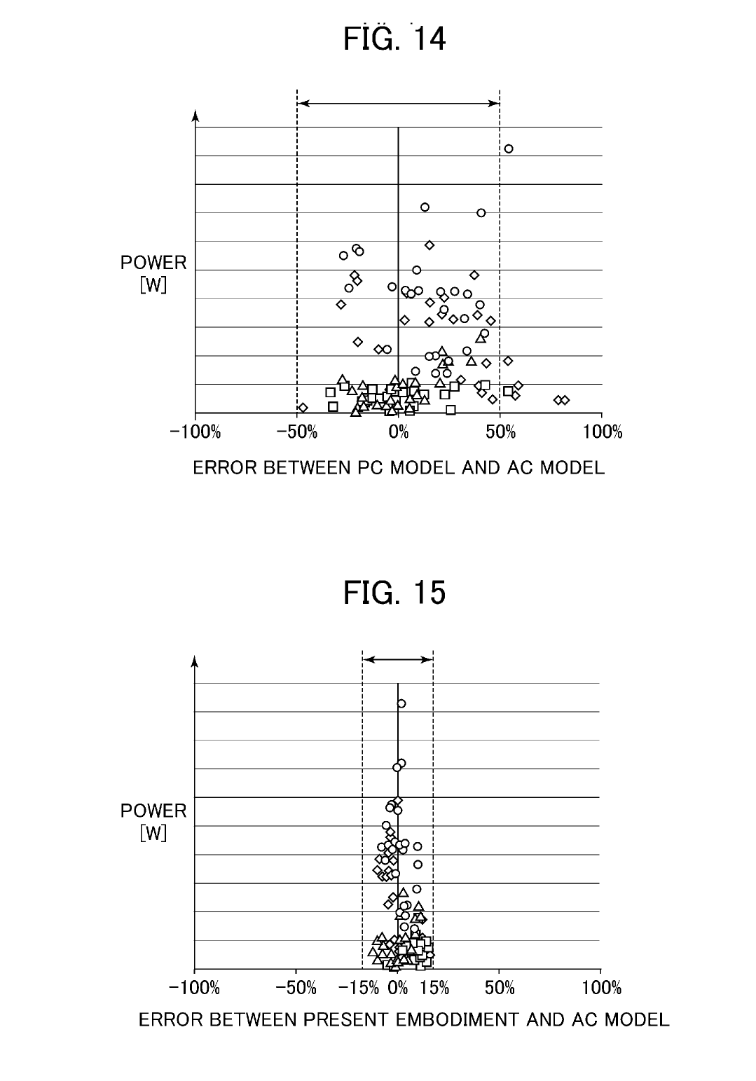

The results of verification are shown below in FIGS. 14 and 15.

FIG. 14 is a graph showing the difference between power consumption calculated by the AC model and power consumption calculated by the DC model. FIG. 15 is a graph showing the difference between power consumption calculated by the AC model and power consumption calculated by the method of the present embodiment. The horizontal axis of the graph indicates the difference in power consumption, and the vertical axis indicates power consumption calculated by the AC model.

Referring to FIG. 14, it is found that the power consumption calculated by the DC model has caused an error of 50% or more with respect to the power consumption calculated by the AC model.

On the other hand, the power consumption calculated by the method of the exemplary embodiment remains within a difference of 15% or so with respect to the power consumption calculated by the AC model. Thus, the method of the exemplary embodiment proves to be a method effective in estimating the power consumption.

Many widely different embodiments may be configured without departing from the spirit and the scope of the present invention. It should be understood that the present invention is not limited to the specific embodiments described in the specification, except as defined in the appended claims.

The disclosure is directed to an apparatus which calculates power consumption of each of gradient coils, and the apparatus can calculate the power consumption in a short time.

1. A calculating apparatus comprising:
a resistance calculating unit configured to calculate, based on a pulse width of a gradient pulse generated by a gradient coil, a resistance of the gradient coil at the time that the gradient coil generates the gradient pulse; and
a power consumption calculating unit configured to calculate power consumption of the gradient coil, based on the resistance of the gradient coil.

2. The calculating apparatus according to claim 1, wherein the resistance calculating unit is configured to calculate the resistance of the gradient coil, based on parameters determined by the gradient coil and the pulse width.

3. The calculating apparatus according to claim 2, further comprising a pulse width calculating unit configured to calculate the pulse width, based on point data indicative of characteristic points of a waveform of the gradient pulse.

4. The calculating apparatus according to claim 3, further comprising a coil current calculating unit configured to calculate a coil current of the gradient coil, based on the point data.

5. The calculating apparatus according to claim 4, wherein the coil current calculating unit is configured to calculate a gradient magnetic field intensity of the gradient coil, based on the point data and configured to calculate the coil current, based on the gradient magnetic field intensity.

6. The calculating apparatus according to claim 5, wherein the characteristic points of the waveform of the gradient pulse are a point at which a gradient of the gradient pulse changes, and a point at which the gradient magnetic field intensity of the gradient pulse is zero.

7. A magnetic resonance system having a gradient coil, the magnetic resonance system comprising:
a resistance calculating unit configured to calculate, based on a pulse width of a gradient pulse generated by the gradient coil, a resistance of the gradient coil at the time that the gradient coil generates the gradient pulse; and
a power consumption calculating unit configured to calculate power consumption of the gradient coil, based on the resistance of the gradient coil.

8. The magnetic resonance system according to claim 7, wherein the resistance calculating unit is configured to calculate the resistance of the gradient coil, based on parameters determined by the gradient coil and the pulse width.

9. The magnetic resonance system according to claim 8, further comprising a pulse width calculating unit configured to calculate the pulse width, based on point data indicative of characteristic points of a waveform of the gradient pulse.

10. The magnetic resonance system according to claim 9, further comprising a coil current calculating unit configured to calculate a coil current of the gradient coil, based on the point data.

11. The magnetic resonance system according to claim 10, wherein the coil current calculating unit is configured to calculate a gradient magnetic field intensity of the gradient coil, based on the point data and configured to calculate the coil current, based on the gradient magnetic field intensity.

12. The magnetic resonance system according to claim 11, wherein the characteristic points of the waveform of the gradient pulse are a point at which a gradient of the gradient pulse changes, and a point at which the gradient magnetic field intensity of the gradient pulse is zero.

13. A power consumption calculating method comprising:
calculating, based on a pulse width of a gradient pulse generated by a gradient coil, a resistance of the gradient coil at the time that the gradient coil generates the gradient pulse; and
calculating power consumption of the gradient coil, based on the resistance of the gradient coil.

14. The power consumption calculating method according to claim 13, wherein calculating a resistance comprises calculating the resistance of the gradient coil, based on parameters determined by the gradient coil and the pulse width.

15. The power consumption calculating method according to claim 14, further comprising calculating the pulse width, based on point data indicative of characteristic points of a waveform of the gradient pulse.

16. The power consumption calculating method according to claim 15, further comprising calculating a coil current of the gradient coil, based on the point data.

17. The power consumption calculating method according to claim 16, wherein calculating the coil current comprises calculating a gradient magnetic field intensity of the gradient coil, based on the point data and calculating the coil current, based on the gradient magnetic field intensity.

18. The power consumption calculating method according to claim 17, wherein the characteristic points of the waveform of the gradient pulse are a point at which a gradient of the gradient pulse changes, and a point at which the gradient magnetic field intensity of the gradient pulse is zero.

19. A program configured to cause a computer to execute:
a resistance calculating process that calculates, based on a pulse width of a gradient pulse generated by a gradient coil, a resistance of the gradient coil at the time that the gradient coil generates the gradient pulse; and
a power consumption calculating process that calculates power consumption of the gradient coil, based on the resistance of the gradient coil.

20. The program according to claim 19, wherein the resistance calculating process calculates the resistance of the gradient coil, based on parameters determined by the gradient coil and the pulse width.
